(19) United States
(12) Patent Application Publication
(10) Pub. No.: US 2008/0068987 A1
(43) Pub. Date: Mar. 20, 2008

(54) Loop network system and data storage devices included therein

(75) Inventors: Mutsuya Hida, Kanagawa (JP); Akira Kojima, Kanagawa (JP); Takeshi Shikama, Kanagawa (JP); Yoshinori Makita, Kanagawa (JP)

Correspondence Address: TOWNSEND AND TOWNSEND AND CREW LLP, TWO EMBARCADERO CENTER, 8TH FLOOR, SAN FRANCISCO, CA, 94111, US

(73) Assignee: Hitachi Global Storage Technologies Netherlands B.V., Amsterdam (NL)

(21) Appl. No.: 11/897,054

(22) Filed: Aug. 28, 2007

(30) Foreign Application Priority Data
Aug. 29, 2006 (JP) 2006-231652

(51) Int. Cl. G01R 31/08; H04L 12/42

(52) U.S. Cl. 370/222; 370/453

(57) ABSTRACT

Embodiments of the present invention provide a loop network system and data storage devices connected thereto where the data storage devices (nodes) can perform effective pieces of processing and the probability of error occurrence can be reduced. One embodiment according to the present invention includes a Fibre Channel Arbitrated Loop network, a Host controller and multiple HDDs connected thereto. A port on the network outputs parameters to control loop initialization processing as well as a LIP Order Set. Each port performs loop initialization processing according to the received parameters and transfers the received LIP Order Set with parameters appended to the down stream.

### CROSS-REFERENCE TO RELATED APPLICATION

The instant nonprovisional patent application claims priority to Japanese Patent Application No. 2006-231652, filed Aug. 29, 2006 and which is incorporated by reference in its entirety herein for all purposes.

### BACKGROUND OF THE INVENTION

Today, in the interfaces of storage devices, speeding up of data transfer, increases in the number of connected devices per host controller, and the increase of connection distances are desired with the increasing volume of data to be handled. To meet these demands, the number of systems configured with devices that perform high-speed serial data transfer through Fibre Channel Arbitrated Loops (FC_ALs) has recently increased.

Generally speaking, in order to interconnect the devices of a computer system including Fibre Channel Arbitrated Loops, each device that is connected to exchange information with other devices must have a kind of unique electronic address or identification information. This address is called an AL_PA (Arbitrated Loop Physical Address), and all the nodes connected to the loop can acquire their own AL_PAs when the nodes are powered on and participate in loop initialization processing. Here it is assumed that the nodes connected to the network include a host controller and other nodes.

The movement of the loop initialization processing and some functions peculiar to a Fibre Channel device can be controlled by setting parameters on Mode Page 19h (Fibre Channel Port Control Page). Currently available parameters are DTOLI (Disable Target Originated Loop Initialization), DTIPE (Disable Target Initiated Port Enable), ALWLI (Allow Login Without Loop Initialization) RHA (Require Hard Address), DLM (Disable Loop Master), DDIS (Disable Discovery), PLPB (Prevent Loop Port Bypass), DTFD (Disable Target Fabric Discovery), RR_TOV (Resource Recovery Time-out Value).

The loop initialization processing is started by at least the port of one node sending LIP (Loop Initialization Primitive) Order Set after the power-on or the reset of the system. A port is part of a node connected to the network, and performs communication. DTOLI is a parameter that controls whether a node itself sends A LIP Order Set or not when the node is connected to the loop. If the ports of all the nodes on the loop have DTOLIs set valid, there are no polls to send A LIP Order Set, that is, a loop initialization start signal, and the loop initialization is not performed so that it may be impossible to communicate between the host controller and each device, which must be paid attention.

FIG. 22 shows a flowchart of the loop initialization processing. Each port that receives a LIP Order Set (S2201) generates a Select Master (Loop Initialization Select Master (LISM)) frame to control frames that are used in the loop initialization processing, and sends it after the port neglects the LIP Order Set, or while the port is neglecting the LIP Order Set during AL_TIME (S2202). Each node that generates a LISM frame has the world wide identification number (world-wide name) as part of the frame. Receiving a LISM frame, each port compares the identification number in the frame with its own identification number. If its own identification number is smaller than the identification number in the frame, the port replaces the identification number in the frame with its own identification number, and then sends the LISM frame with the replaced frame number to the next port. If its own identification number is larger than the identification number in the frame, the port sends the LISM frame with the identification number intact to the next port. Conclusively, all the LISM frames have the smallest identification number of the identification numbers of all the ports connected to the loop. Then the node that has this minimum identification number becomes Loop Master. In FIG. 22, the processing by the port that is Loop Master is shown by S2203 to S2211, while the processing by the ports that are Non-Loop Masters is shown by S2220 to S2228.

Loop Master sends Arb (F0) signal to inform each port on the loop that LISM processing is completed (S2203, S2220). DLM is a parameter that controls whether a node is allowed to be Loop Master or not. If all the nodes on the loop are not allowed to be Loop Master by DLM setting, the loop initialization processing is not completed. Therefore attention must be paid to DLM setting.

The port of the node of Loop Master generates a frame that decides AL_PAs of the ports on the loop. This frame is divided into two portions, that is, the frame identification portion and the address information portion. The latter portion has a numeric value of 127 bits, and each bit is corresponding to an AL_PA. Each port sets a flag to a bit corresponding to the AL_PA it wants to acquire according to the after-mentioned rule and sends the frame to the subsequent ports. When the frame returns to the port of Loop Master in this way, the port of Loop Master switches the frame identification portion while leaving the address information portion intact and sends the frame to the subsequent ports.

The port that becomes Loop Master first generates Fabric Assigned (Loop Initialization Fabric Assigned (LIFA)) frame and sends it to the ports in the downstream (S2204). The other ports send the received frame to the subsequent ports. This frame is used to judge whether a port is also a port to Fibre Channel Fabric or not. DTFD is a parameter that controls whether a port is the port to Fibre Channel Fabric or not.

The port that becomes Loop Master next switches the frame identification portion to Loop Initialization Previous Acquired (LIPA) frame and sends the frame to the subsequent ports (S2205). If each node has already acquired an AL_PA before the currently ongoing initialization, the node sets the corresponding flag to the address information portion and sends the frame to the subsequent ports (S2222).

The port that becomes Loop Master next switches the frame identification portion to Loop Initialization Hard Assigned (LIHA) and sends the frame to the subsequent ports (S2206). After performing necessary processing on the received frame, the other ports transfer the frame to the subsequent ports (S2223). If this loop initialization is the first one to all the ports on the loop, there are no bits set in the address information portion of the LIHA frame. Each port sets the bit corresponding to its hard address in the address information portion of 127 bits. If the corresponding bit in the address information portion has been already set, each port tries to acquire an AL_PA with the use of after-mentioned soft addressing.

The port that becomes Loop Master next switches the frame identification portion to Loop Initialization Soft Assigned (LISA) frame and sends the frame to the subsequent ports (S2207). After performing necessary processing on the received frame, the other ports transfer the frame to the subsequent ports (S2224). If each port can not select an address during the processing of the above-mentioned LIHA frame or before, it selects any available loop address referring the address information portion, and sets the suitable bit to the address number of the 127 bits of the frame. Then the port sends the frame to the subsequent ports.

RHA is a parameter that controls whether soft addressing is performed or not. If multiple ports, which have RHAs set valid and have the same settings of the connection units, exist on the loop, only the port nearest to Loop Master can acquire the corresponding AL_PA through the LIHA processing, and the other ports can not acquire AL_PAs through the LIHA processing. Therefore, attention must be paid to the address setting of the connectors when this control is used.

The port that becomes Loop Master next judges whether all the ports on the loop support Loop Position Map or not from the returned LISA frame (S2085). The other ports perform the similar processing (S2225). If even only one port does not support Loop Position Map, Loop Master sends CLS signal (S2211). After receiving CLS signal, the other ports send CLS signal to the subsequent ports (S2228). The loop initialization processing is completed when CLS signal returns back to Loop Master.

If all the ports support Loop Position Map, the port that has newly become Loop Master generates Loop Initialization Report Position frame, and sends the frame to the subsequent ports after setting its own information (S2209). This frame consists of a frame identification portion and an AL_PA information portion of 128 bytes. The first one byte of the AL_PA information portion shows the offset number on the loop, and AL_PAs that are actually acquired by the ports are set to the second byte and later. A port that receives LIRP sets an AL_PA that the port has already acquired to the position corresponding to the offset number of the AL_PA information portion, and then sends the frame to the subsequent ports. If a port has not acquired an AL_PA yet, the port sends the LIRP without modification to the subsequent ports (S2226).

The port that becomes Loop Master next switches the frame identification portion of the returned LIRP frame to Loop Initialization Loop Position (LILP) and sends the frame to the subsequent port (Step S2210). After performing necessary processing on the received frame, the other ports transfer the frame to the subsequent ports (S2227). By referring LILP, the number of ports that are participating in this loop initialization, the AL_PA of Loop Master, and the order of the AL_PAs of the subsequent ports can be grasped.

When LILP signal finally returns back to the port that becomes Loop Master, the port that is Loop Master sends CLS signal (S2221). When CLS signal returns back to Loop Master after going around the loop (S2228), the loop initialization processing is completed.

On above-mentioned Mode Page 19h, DTIPE is a parameter that controls whether a device itself enables Port Bypass Circuit or disables Port Bypass Circuit until the device receives Loop Port Enable (LPE) signal when the device is connected to the loop. ALWLI is a parameter that controls whether a device can perform LOGIN processing without initialization processing performed. In this instance, AL_PAs are decided on the basis of information directly set to connectors so that there is a possibility that address contention problems will occur, which must be paid attention.

DDIS is a parameter that controls whether discovery processing usually performed by the host controller after loop initialization processing is completed is suppressed or not. PLPB is a parameter that controls whether Loop Port Enable (LPE) signal and Loop Port Disable (LPB) signal are neglected or not. Finally RR_TOV is a parameter that is used to set the time of authentication period for a port after the loop initialization is completed. The path setting for a node connected to a loop network other than a FC_AL is disclosed in Japanese Patent Publication No. 2004-140570 (“Patent Document 1”).

As described above, now Mode Page 19h (Fibre Channel Port Page) is prepared to offer parameters used for loop initialization processing and for other controls of a Fibre Channel. And the controls suitable to a system can be performed by setting these parameters optionally.

However, as shown in FIG. 23, in order for these parameters to be used for controlling the behaviors of a device, the setting values for these parameters must be stored in a volatile part such as a flash memory before the device is connected to a loop. To be concrete, when the device is powered on (S2301), mode parameters are read out from the volatile part (S2302), and set in the loop initialization setting table (S2304). In this instance, if even only one device on the loop has a wrong setting value or the reference is not performed correctly, the port on the loop behaves accidentally so that an unexpected failure may occur or the loop may be choked.

In another instance, as shown in FIG. 23, in order to change this mode page, after loop initialization is completed and the host controller and devices acquire AL_PAs, LOGIN processing and Mode Select command processing must be performed (S20303). However there is a problem in that it takes considerable time to perform these pieces of processing. In addition, if the same parameters are to be set to multiple ports connected to the loop, the LOGIN processing and the Mode Select processing must be performed to each port individually with the result that it takes longer time.

While a LIP Order Set is used for acquiring AL_PAs, it can be also used as a recovering means when a loop is choked because signals on the loop are lost due to noises and the like. This is achieved because each port must participate in loop initialization with the highest priority when receiving a LIP Order Set even if it is performing an I/O processing. If a loop initialization frame is broken during the loop initialization, the AL_PA of each port changes so that there is a possibility that system failure will occur.

### BRIEF SUMMARY OF THE INVENTION

Embodiments in accordance with the present invention provide a loop network system and data storage devices connected thereto, where the data storage devices (nodes) can perform effective pieces of processing and the probability of error occurrence can be reduced. The particular embodiment of FIG. 2 includes a Fibre Channel Arbitrated Loop network and a Host controller 2 and multiple HDDs (HDD 1a to HDD 1d) connected thereto. A port on the network outputs parameters to control loop initialization processing as well as a LIP Order Set. Each port performs loop initialization processing according to the received parameters and transfers the received LIP Order Set with parameters appended to the down stream.

### BRIEF DESCRIPTION OF THE DRAWINGS

FIG. 1 is a block diagram showing the total configuration of an HDD related to the applicable embodiment of the present invention schematically.

FIG. 2 is a diagram showing the loop network system related to an applicable embodiment of the present invention schematically.

FIG. 3 is a block diagram showing logical components that execute loop initialization processing related to an applicable embodiment of the present invention schematically.

FIG. 4 is a diagram showing the format of a Mode Page 19h in the FC-AL system.

FIG. 5 is a diagram showing the results of the loop initialization processing with predefined parameters in the connection of FIG. 2.

FIG. 6 shows the values of Mode Page 19h stored beforehand for each HDD, connector jumper setting values, and examples of the AL_PAs corresponding to the connector jumper setting values.

FIG. 7 shows the state of each HDD when it reads the values of Mode Page 19h stored in the EEPROM 25.

FIG. 8 shows the actual loop initialization movement performed according to FIG. 7.

FIG. 9 is a flowchart showing an example of loop initialization processing with the use of a LIP Order Set of an embodiment of the present invention.

FIG. 10 is a flowchart showing another example of loop initialization processing with the use of a LIP Order Set of an embodiment of the present invention.

FIG. 11 shows the bit settings of Setting Modes and so on related to the embodiment of the present invention when LIP (FE, xx) or LIP (FD, xx) is received.

FIG. 12 shows LIP Order Sets used to perform the loop initialization processing movement and Fibre Channel behavior, and the transitions of Setting Modes, the Loop Initialization Movement Control Table, and the authentication times (Units, Value) related to an embodiment of the present invention when these LIP Order Sets are received.

FIG. 13 shows Loop Initialization Control Table and the value of authentication time for each node updated by the loop initialization processing of an embodiment of the present invention.

FIG. 14 shows the setting the values of each node as the results of the loop initialization processing of an embodiment of the present invention.

FIG. 15 is a flowchart showing LIP signal analysis processing.

FIG. 16 is a flowchart showing the flow of the movement of Setting Mode 0 in FIG. 9.

FIG. 17 is a flowchart showing the flow of the movement of Setting Mode 1 in FIG. 9.

FIG. 18 is a flowchart showing the flow of the movement of Setting Mode 2 in FIG. 9.

FIG. 19 is a flowchart showing the flow of the movement of Setting Mode 3 in FIG. 9.

FIG. 20 is a flowchart showing the flow of the movement of Setting Mode 4 in FIG. 9.

FIG. 21 is a flowchart showing the flow of the movement of Setting Mode 5 in FIG. 9.

FIG. 22 is a flowchart showing the flow of conventional loop initialization processing.

FIG. 23 is a flowchart showing the conventional loop initialization processing.

### DETAILED DESCRIPTION OF THE INVENTION

Embodiments in accordance with the present invention relate to a loop network system and data storage devices included therein, and more particularly, to control of the behaviors of nodes in an information processing system configured with multiple devices connected through a loop structured information transmission line such as a Fibre Channel Arbitrated Loop.

One aspect of embodiments of the present invention is a loop network system that includes a loop network and multiple nodes connected to the loop network. This system includes a control node for sending parameters for controlling initialization processing performed by the nodes to perform data communication in the loop network to the downstream of the loop network system. The system further includes controlled nodes that receives the parameters, performs the initialization processing according to the received parameters, and transfers the received parameters to the downstream of the loop network. Because each node performs the initialization processing according to the received parameters, and transfers the received parameters to the subsequent node, effective processing can be achieved.

The parameters for controlling the initialization processing may be transmitted among nodes in the loop network in the form of appendices to the execution start command of the initialization processing. In this way, the effective data transfer can be achieved. At least part of the multiple nodes may further include nonvolatile storage media to store the parameters for controlling the initialization processing and receive the instruction to store the parameters in the nonvolatile storage media or not as well as the parameters. Because the parameters are stored in the nonvolatile storage media, the parameters can be used without the need for them to be acquired through the network, and at the same time the instruction to store the parameters in the nonvolatile storage media or not allows the control depending on the situation to be performed.

Another aspect of embodiments in accordance with the present invention is a data storage device that is connected to a loop network and is used for data communication. This data storage device includes a receiving unit that receives parameters through the loop network; an initialization control unit that performs initialization processing according to the parameters received by the receiving unit in order to perform data communication in the loop network from the upstream of the loop network; and a transmitting unit that transfers the parameters received by the receiving unit to the downstream of the loop network. Because the parameters for controlling the initialization processing are transferred and the initialization processing is performed according to these parameters, effective processing can be achieved.

The data storage device may further include nonvolatile storage media for storing parameters for controlling the initialization processing and overwrites the parameters stored in the nonvolatile storage media according to the instruction received with the parameters. The receiving unit may receive the parameters for controlling the initialization processing as well as the execution start command of the initialization processing and the transmitting unit transmits the parameters for controlling the initialization processing as well as the execution start command of the initialization processing.

Another aspect of embodiments in accordance with the present invention is a loop network system that includes a loop network and multiple nodes connected the loop network. When one of the multiple nodes judges whether the loop is choked, the node sends a control signal according to which each node performs processing as well as a preset identifier even if the loop is choked. The other multiple nodes start the processing corresponding to the sent control signal, and at the same time omits at least part of the ordinal processing corresponding to the control signal according to the identifier. With the use of the control signal, the state of the loop being choked is solved, and at the same time at least part of the ordinal processing is omitted, with the result that the processing time and the error probability of the ordinal processing can be reduced.

In an example of an embodiment in accordance with the present invention, the control signal instructs how to perform loop initialization processing, and each of the multiple nodes omits the acquisition processing of an address on the loop network in the loop initialization processing, with the result that the processing time in the address acquisition processing, and the error probability can be reduced.

Another aspect of embodiments in accordance with the present invention is a data storage device that is connected to a loop network and is used for data communication. The data storage device includes a judgment unit that judges whether the loop is choked; a transmitting unit that sends a control signal according to which processing is performed as well as a preset identifier even when the loop is choked; and a control unit that performs the processing according to the control signal, while omitting at least part of the ordinal processing corresponding the control signal. With the use of the control signal, the state of the loop being choked is solved, and at the same time at least part of the ordinal processing is omitted, with the result that the processing time and the error probability of the ordinal processing can be reduced. The control signal may instruct how to perform loop initialization processing, and the control unit omits the acquisition processing of an address on the loop network.

Embodiments in accordance with the present invention allow the nodes connected to loop network to perform effective processing and also allows the probability of error occurrence to be reduced.

An applicable embodiment for carrying out embodiments of the present invention will be described below. To make the explanations clear, the following descriptions and drawings will be abbreviated or simplified depending on the situation. In addition, although the same reference numerals are appended to the same elements in each drawing, it is often avoided to append the same reference numerals repeatedly in order to make the explanations clear. In the following descriptions, a hard disk drive is taken as an example of data storage devices to describe the applicable embodiments in accordance with the present invention. An HDD that is an example of node is connected to a loop network, and the loop network and the nodes connected thereto constitute a network system.

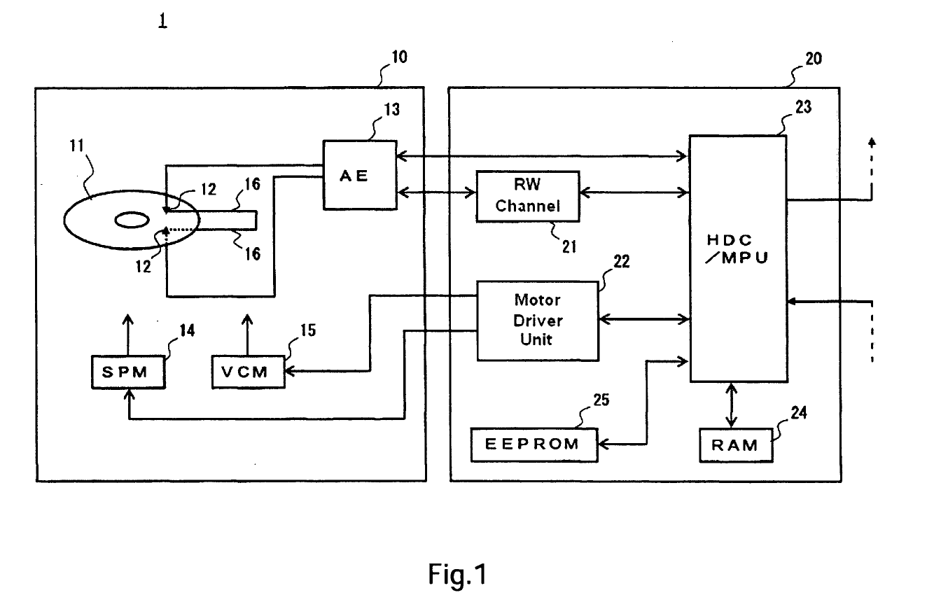

This embodiment of the present invention is characterized by the control of the processing performed by the HDD connected to the loop network. FIG. 1 is a block diagram showing the total configuration of an HDD 1 schematically. As shown in FIG. 1, the HDD 1 includes a magnetic disc 11 that is an example of disc for storing data, a head element unit 12, an arm electronic circuit (arm electronics: AE) 13, a spindle motor (SPM) 14, a voice coil motor (VCM) 15, and an actuator 16 in an enclosure 10. The HDD 1 is equipped with a circuit board 20 fixed outside the enclosure 10. On the circuit board 20 are various ICs such as a read/write channel (RW channel) 21, a motor driver unit 22, an integrated circuit of a hard disk controller (HDC) and an MPU (HDC/MPU for short hereafter) 23, a RAM 24, and an EPROM 25 mounted. In this instance, these circuits can be integrated into one IC, or can be divided to be implemented in the multiple ICs. SPM 14 rotates the magnetic disc 11 fixed thereto at the predefined angular velocity. The motor driver unit 22 drives SPM 14 according to the control data sent by HDC/MPU 23. Both sides of the magnetic disc 11 of this example function as recording surfaces, and the head element unit 12 is equipped with two heads corresponding to the both recording surfaces respectively. Each head of the head element unit 12 is fixed to a slider (not shown). In addition, the slider is fixed to the actuator 16 that are examples of head moving mechanisms. During data read/write period, the slider lifts the revolving magnetic disc 11. The actuator 16, which is connected to VCM 15, moves the head element unit 12 (and the slider) in the radius direction on the magnetic disc 11 by revolving and moving around a revolving and moving axis.

The motor driver unit 22 drives VCM 15 according to the control data sent by HDC/MPU 23. The head element unit 12 is typically equipped with write elements that convert electric signals to magnetic fields according to write data and read elements that convert magnetic fields output from the magnetic disc 11 to electric signals. In this embodiment of the present invention, either one magnetic disc 11 or more will do, while one side or both sides of the magnetic disc 11 can be recording surfaces. In addition, the present invention call be applied to a data storage device with only read elements equipped.

AE 13 selects one head element unit 12 out of the multiple head element units 12 and amplifies (pre-amplifies) signals that are reproduced by the selected head element unit 12 with a constant gain, and sends the signals to RW channel 21. AE 13 also sends signals that are sent from RW channel 21 to be recorded, to the selected head element unit 12. In write processing, RW channel 21 performs code modulation on write data sent by HDC/MPU 23, converts the code modulated write data to write signals, and sends the write signals to AE 13. In read processing, RW channel amplifies read signals sent by AE 13 so that the signals have a constant amplitude, extracts data from the acquired read data, and performs decode processing on the extracted data. Read data includes user data and servo data. Decoded data is sent to HDC/MPU 23.

In HDC/MPU 23, MPU behaves according to micro codes loaded into the RAM 24. When the HDD 1 is started up, the micro codes that run on MPU, data needed for control and data processing are loaded into the RAM 24 from the magnetic disc 11 or a ROM in HDC/MPU 23. In addition, needed parameters are loaded into the RAM 24 from the EEPROM 25. HDC is constituted by logical circuits, and performs various pieces of processing in conjunction with MPU. For example, HDC/MPU 23 performs various pieces of processing needed for data processing such as management of command execution order, positioning control of the head element unit 12, interface control, defect management. Particularly, HDC/MPU 23 of this embodiment of the present invention performs the interface processing and the internal processing of the loop network in which the HDD 1 is participating.

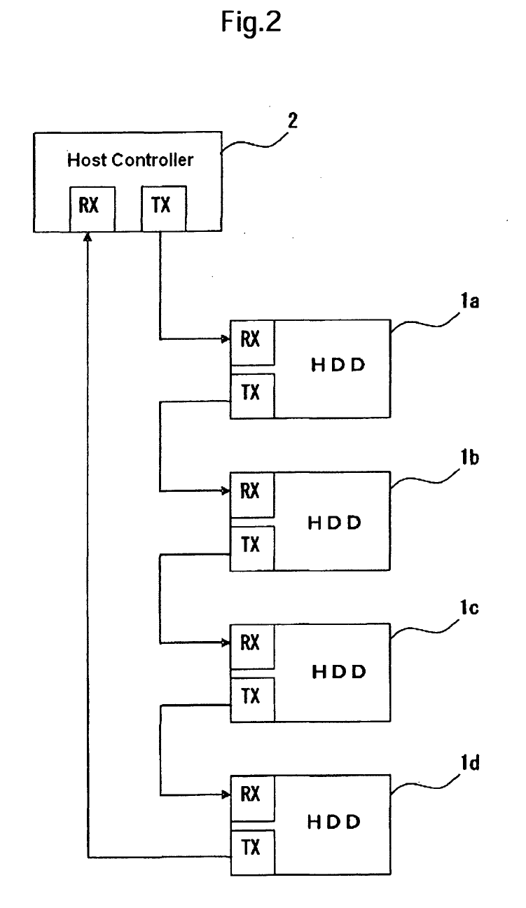

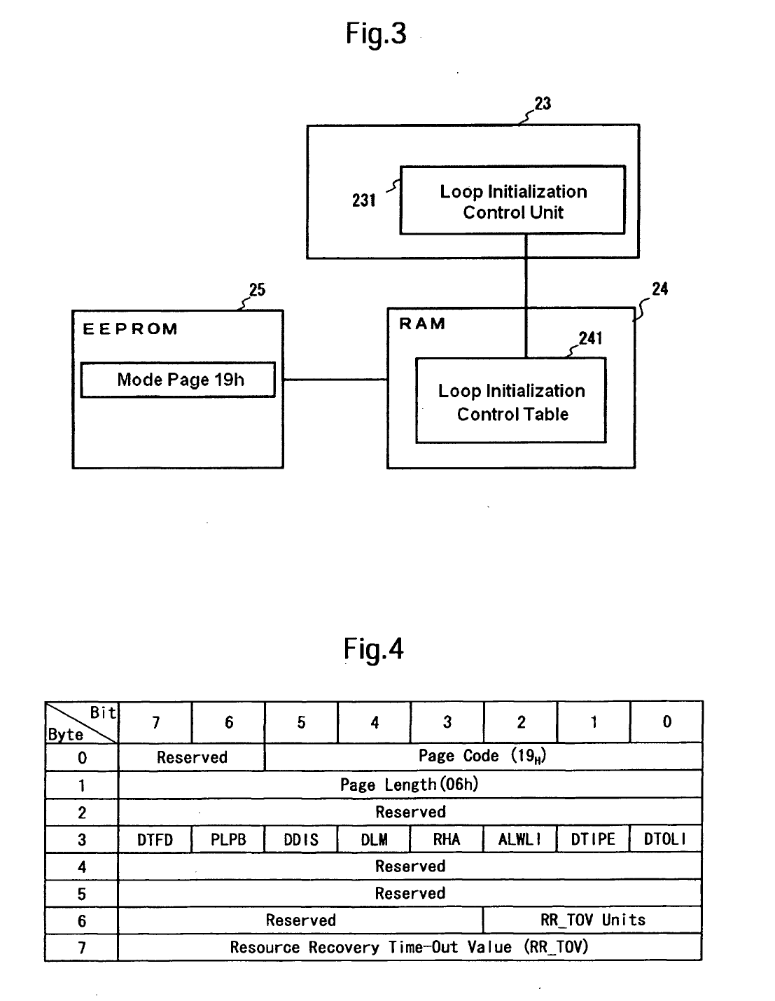

Next, as an example of loop network according to an embodiment of the present invention, a Fibre Channel Arbitrated Loop system as shown in FIG. 2 will be described. This system is configured with a single loop to which a host controller 2 and four HDDs, HDD 1a to HDD 1d. In the FC-AL system, the port of the host controller 2, which is one of the nodes, generates a LIP Order Set that includes parameters for controlling loop initialization processing performed by the other ports (HDD 1a to HDD 1d), and sends the LIP Order Set to the ports of the downstream of the network. When receiving the LIP Order Set that includes the parameters, each port holds the parameters, and transfers the LIP Order Set to the subsequent HDD 1 or the host controller 2. Each port performs loop initialization processing according to the parameters that it holds. The address of each node (port) on the network is decided in the loop initialization processing. Each port performs initialization processing as a function implemented in itself. To be concrete, as shown schematically in a block diagram of FIG. 3, the initialization processing is performed by HDC/MPU 23 as a function of a loop initialization control unit 231.

The loop initialization control unit 231 loads the parameters related to the loop initialization among parameters on Mode Page 19h that are stored in the EEPROM 25 to the RAM 24, and set these parameters in Loop Initialization Control Table 241. Mode Page 19h is shown in FIG. 4. The loop initialization control unit 231 has a function that judges LIP (Loop Initialization Primitive) Order Set is an ordinal LIP Order Set or a LIP Order Set including parameters for loop initialization processing when receiving the LIP Order Set. If the LIP Order Set is a LIP Order Set including parameters for loop initialization processing, the loop initialization control unit 231 sets the parameters in Loop Initialization Control Table 241 of the RAM 24. In addition, the loop initialization control unit 231 performs loop initialization processing according to the parameters set in Loop Initialization Control Table 241, and decides addresses on the network.

The following five LIP Order Sets are used in conventional FC-AL systems:

(1) LIP (F7, F7): Loop Initialization no valid AL_PA

(2) LIP (F8, F7): Loop Failure no valid AL_PA

(3) LIP (F7, AL_PS): Loop Initialization valid AL_PA

(4) LIP (F8, AL_Ps): Loop Failure valid AL_PA

(5) LIP (AL_PD, AL_PS): reset L_Port

In this instance, the format of the LIP Order Sets is LIP (X, Y), where K represents “destination address”, and Y represents “sender address”. F7 means the broadcast under the state that AL_PAs have not been allocated yet. F8 means the broadcast under the state that the signals are not received in the predefined period. AL_PD is an AL_PA of a destination, and AL_PS is an AL_PA of a sender. In other words, in conventional LIP Order Sets, even when the conventional LIP Order Sets are sent to all the HDDs connected in a loop, temporary addresses such as F7 or F8 is used in AL_PAs.

Compared with conventional LIP Order Sets, the following will be described below as LIP Order Sets (LIP (yy, xx)) related to this applicable embodiment of the present invention. One is loop initialization movement parameter storage mode: LIP (FE, xx). Another is loop initialization movement parameter non-storage mode: LIP (FD, xx). These LIP Order Sets related to this applicable embodiment of the present invention are sent to all the HDDs, HDD 1a to HDD 1d, connected in a loop to set parameters for initialization control collectively to all the HDDs. Therefore, unlike the conventional LIP Order Sets, these LIP Order Sets need neither destination addresses nor sender addresses so that it is not required to specify AL_PDs or AL_PSs in these LIP Order Sets.

As to “xx” in LIP (FE, xx) and LIP (FD, xx), one method is to put a parameter in the column Byte 3 of current Mode Page 19h (Fibre Channel Control Page) to “xx” as it is, but the values of some parameters are not recognized as Fibre Channel signals because they are taken for error codes. Therefore, let's examine another method with parameters other than those in the column Byte 3 of Mode Page 19h taken into consideration.

Setting up loop initialization movement parameter storage mode and loop initialization movement parameter non-storage mode to the LIP Order Sets allows each of HDD 1a to HDD 1d to judge whether a parameter is stored in the EEPROM 25 or not after setting the parameter in Loop Initialization Control Table 241. In other words, a HDD (port) that receives the LIP Order Set with loop initialization movement parameter storage mode overwrites the corresponding information of Mode Page 19h stored in the EEPROM 25 with the received parameter.

A HDD (port) that receives the LIP Order Set with loop initialization movement parameter non-storage mode does not overwrite the corresponding information of Mode Page 19h stored in the EEPROM 25. As a consequence, unlike the control by conventional Mode Select commands, the change of Mode Page can be performed to nodes that have not acquired AL_PAs or have not undergone LOGIN processing.

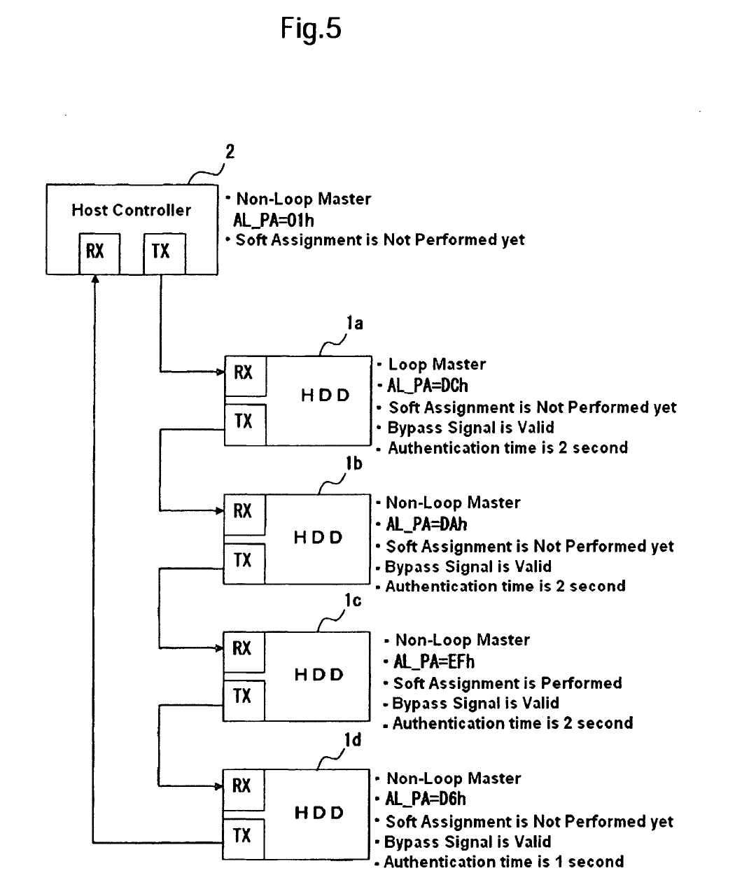

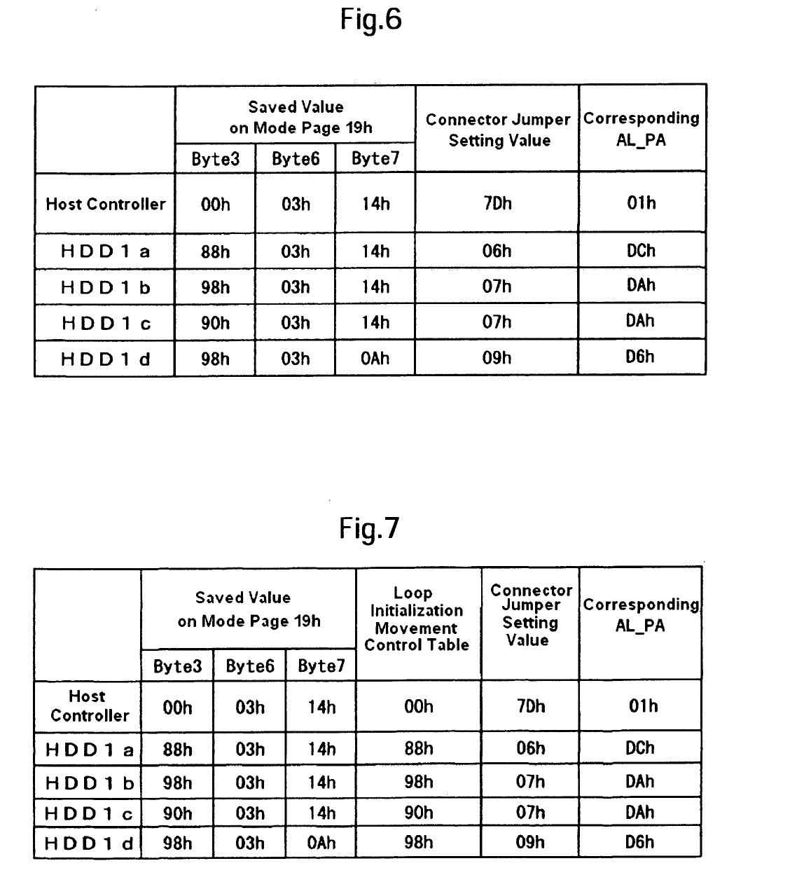

As an example of the present invention, the behaviors of devices shown in FIG. 2 will be described when the setting values to the devices are the values shown in FIG. 5 and FIG. 6. FIG. 6 shows the values of Mode Page 19h stored beforehand for HDD 1a to HDD 1d in the EEPROM 25, connector jumper setting values, the AL_PAs corresponding to the connector jumper setting values. Here it is assumed that the magnitude relation among the world wide identification numbers (world-wide names) of the Fibre Channels of the ports according to which Loop Master is decided is as follows:

WWN of HDD 1a port<WWN of the host controller port<WWN of HDD 1b port<WWN of HDD 1c port<WWN of HDD 1d port.

Therefore Loop Master is HDD 1a (the device 1). In addition, it is assumed that the connector jumper setting value for the device 3 is 07h instead of the correct value 08h.

The loop initialization movement and the Fibre Channel control parameters that the host controller expects are assumed to be as follows:

(1-a) The host controller becomes Loop Master.

(1-b) AL_PAs of four HDDs on the loop are expected to be as follows:
HDD 1a: DCh; HDD1b: DAh; HDD 1c: D9h; and HDD 1d: D6h

(1-c) Each of HDD 1a to HDD 1d does not perform soft assignment.

In addition, the other Fibre Channel behavior is assumed to be as follows:

(1-d) Fabric assignments are suppressed.

(1-e) Bypass primitives are neglected.

(1-f) The authentication periods for all the HDDs are assumed to be 2 seconds.

(1-g) The settings for the loop initialization movement and the Fibre Channel behavior are maintained after the power-off.

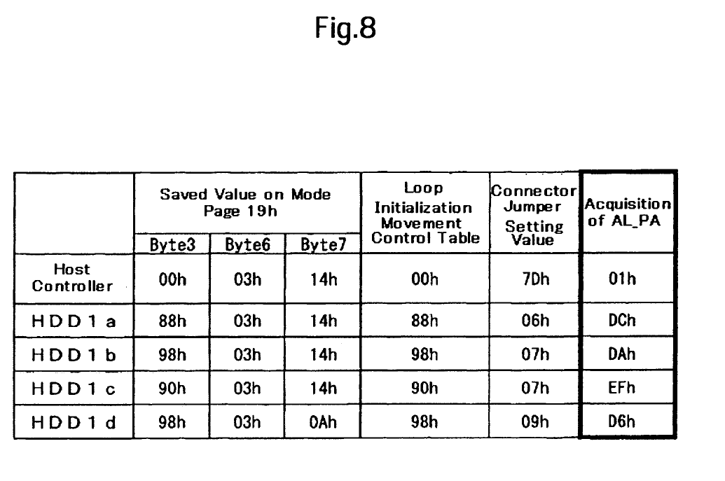

When the power is applied, each of HDD 1a to 1d reads the values of Mode Page 19h (Fibre Channel Control Page) stored in the EEPROM 25 and gets into the state shown in FIG. 7. Each of HDD 1a to HDD 1d begins to perform loop initialization processing depending on the values in the loop initialization movement control table. However, the actual loop initialization movement is performed as shown in FIG. 5 and FIG. 8. In other words, the movement produces the following results:

(2-a) Loop Master is the device 1.

(2-b) HDD 1c performs soft assignment and acquires the value of an AL_PA of EFh.

(2-c) In each of HDD 1a to HDD 1d, the bypass primitive is set valid.

(2-d) The authentication period of HDD 1d becomes 1 second.

As a result, the actually performed loop initialization movement differs from that the host controller expects.

In this instance, the loop initialization movement that the host controller expects is as follows:

(1-a) DLMs (bit 4) of HDD 1a to HDD 1d are set ON.

(1-c) RHAs (bit 3) of HDD 1a to HDD 1d are set ON.

(1-d) DTFDs (bit 7) of HDD 1a to HDD 1d are set ON.

(1-e) PLPBs (bit 6) of HDD 1a to HDD 1d are set ON.

(1-f) PR_TOV Units are set 03h, and Resource Recovery Time-Out Value is 14h.

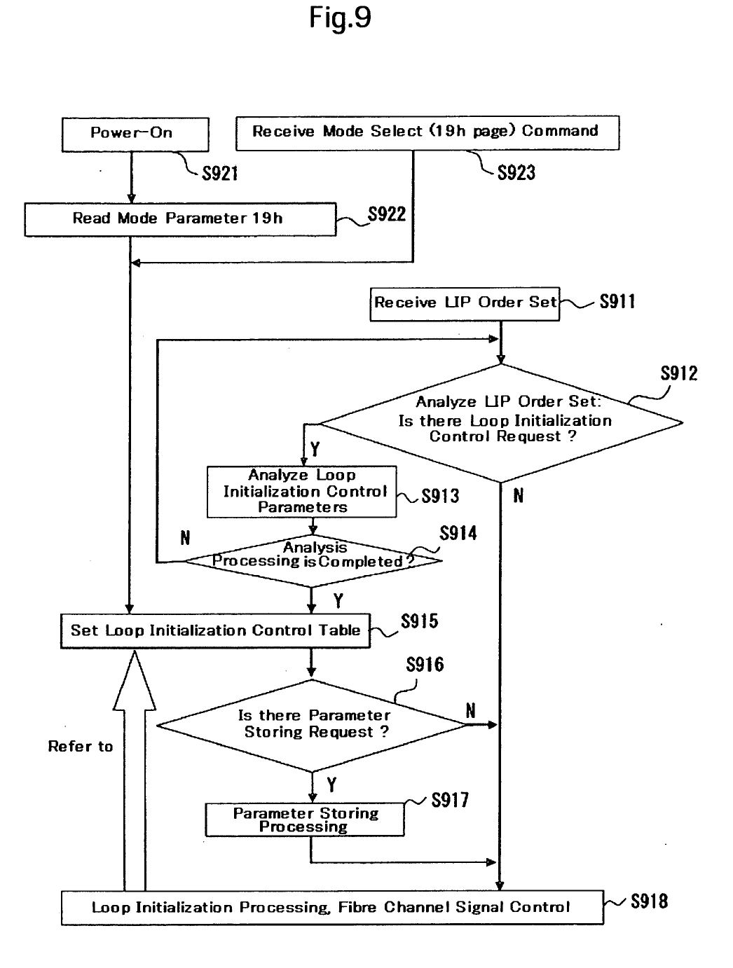

The loop initialization processing related to this embodiment of the present invention will be described below with reference to the flowchart of FIG. 9. As to the setting for Loop Initialization Control Table 241 and the setting for the authentication time, there are six setting modes prepared. The contents of the setting modes and the processing according to the modes will be described later. The loop initialization control unit 231 receives a LIP Order Set (S911), and analyzes the LIP Order Set (S912).

If the LIP Order Set does not have Loop Initialization Control Request (branch N in S912), the loop initialization control unit 231 performs loop initialization processing and Fibre Channel signal control with reference to Loop Initialization Control Table 241 (S918). In this instance, Loop Initialization Control Table 241 has been already set by reading parameters from the EEPROM 25 (S922) when the power was applied (S921) or by Mode Select commands (S923).

If the LIP Order Set has Loop Initialization Control Request (branch Y in S912), the loop initialization control unit 231 analyses the loop initialization control parameters (S913). The processing is repeated until the analysis is completed (branch N in S914). When the analysis is completed (branch Y in S914), the loop initialization control unit 231 sets the value to Loop Initialization Control Table 241 (S915).

It the LIP Order Set has Parameter Storing Request (branch Y in S916), the loop initialization control unit 231 stores the parameters in the EEPROM 25 (S917). Then the loop) initialization control unit 231 performs loop initialization processing and Fibre Channel signal control with reference to Loop Initialization Control Table 241 (S918). In this instance, the values set in Step S915 have been already registered in Loop Initialization Control Table 241. If the LIP Order Set does not have Parameter Storing Request (branch N in S916), the loop initialization control unit 231 performs loop initialization processing and Fibre Channel signal control without storing the parameters (S918).

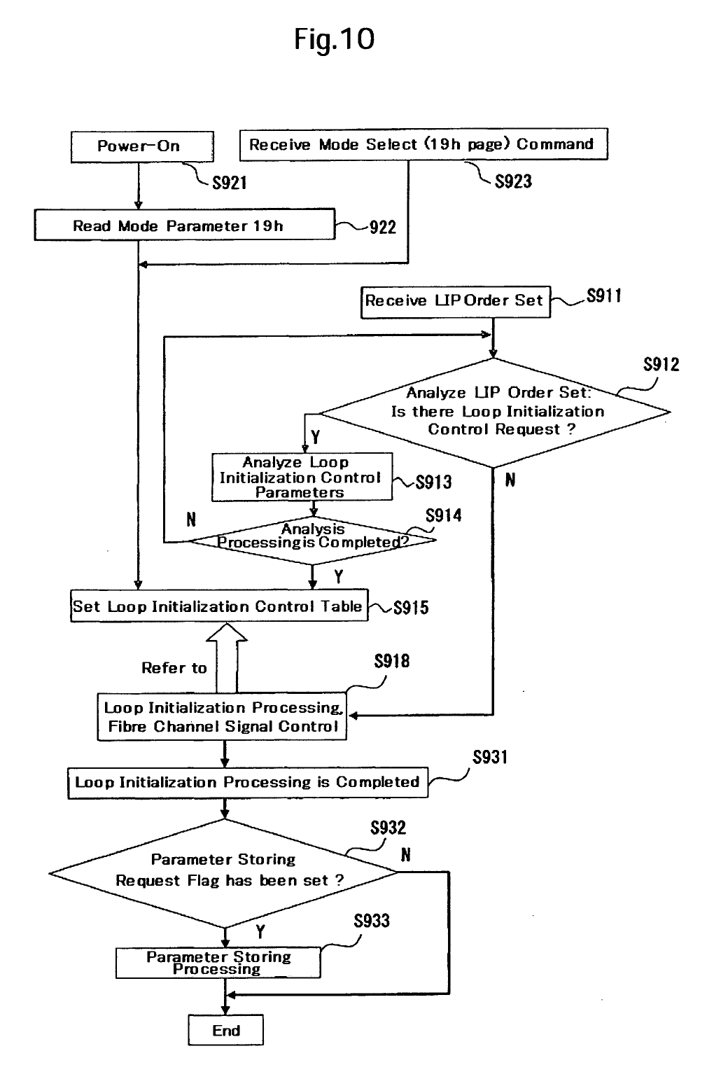

If there is fear that the time-out of the loop initialization processing will occur because it takes a long time to store the parameters in Step S917, the Loop Initialization Control Unit 231 can set a storing request flag, as shown in the flowchart of FIG. 10, and can perform the parameter storage processing after the loop initialization processing is completed. To be concrete, In FIG. 10, the Loop Initialization Control Unit 231 performs loop initialization processing without storing the parameters (S918), and after that (S931) judges whether a parameter storing request flag is set or not (S932). If the parameter storing request flag is not set (branch N in S932), the flow ends without storing the parameters. If the parameter storing request flag is set (branch Y in S932), the Loop Initialization Control Unit 231 stores the parameters in the EEPROM 25 (S933).

The examples of the above-mentioned six setting modes will be described in detail below. These setting modes are as follows:

Setting Mode 0: The state that Loop Initialization Control Table is completed.

Setting Mode 1: The state that the higher 4 bits (bit 7 to bit 4) of Byte 3 in Mode Page 19h in Loop Initialization Control Table is set.

Setting Mode 2: The state that the lower 4 bits (bit 3 to bit 0) of Byte 3 in Mode Page 19h in Loop Initialization Control Table are set.

Setting Mode 3: The state that the lower 3 bits (bit 2 to bit 0) of Byte 6 in Mode Page 19h in Loop Initialization Control Table are set.

Setting Mode 4: The state that the higher 4 bits (bit 7 to bit 4) of Byte 7 in Mode Page 19h in Loop Initialization Control Table are set.

Setting Mode 5: The state that the lower 4 bits (bit 3 to bit 0) of Byte 7 in Mode Page 19h in Loop Initialization Control Table are set.

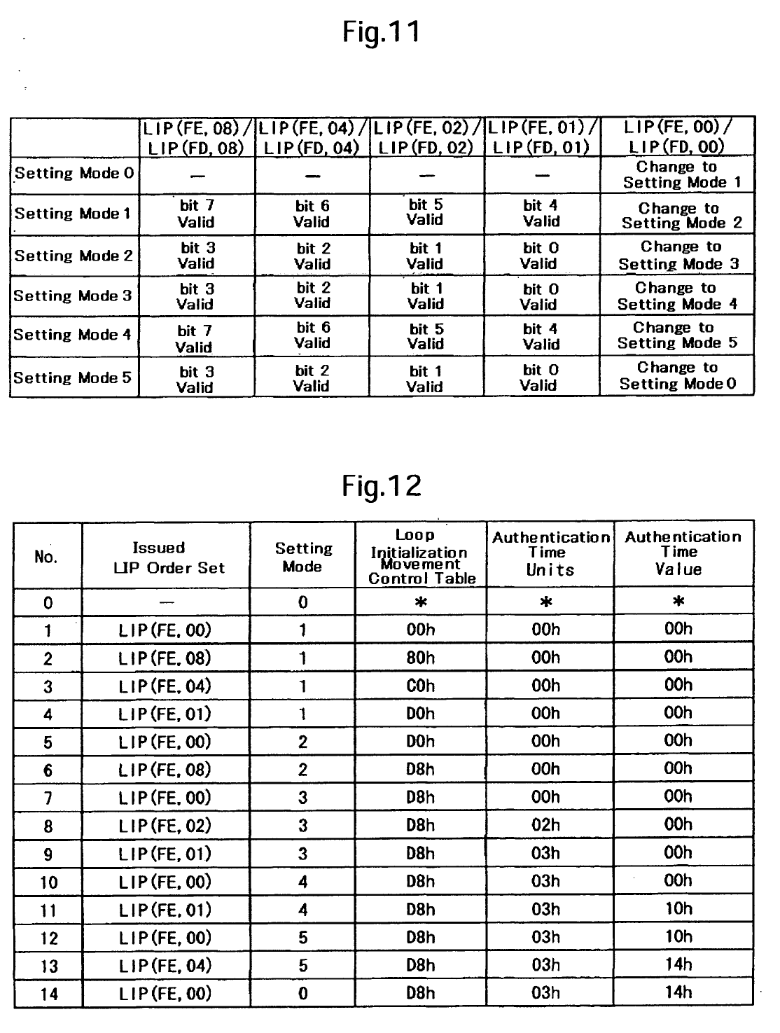

Setting bits of each field ON is performed by LIP (FE, xx), or LIP (FD, xx). FIG. 11 is a table that shows the bit settings of Setting Modes when LIP (FE, xx) or LIP (FD, xx) is received, and transition destinations of Setting Modes when LIP (FE, 00) or LIP (FD, 00) is received.

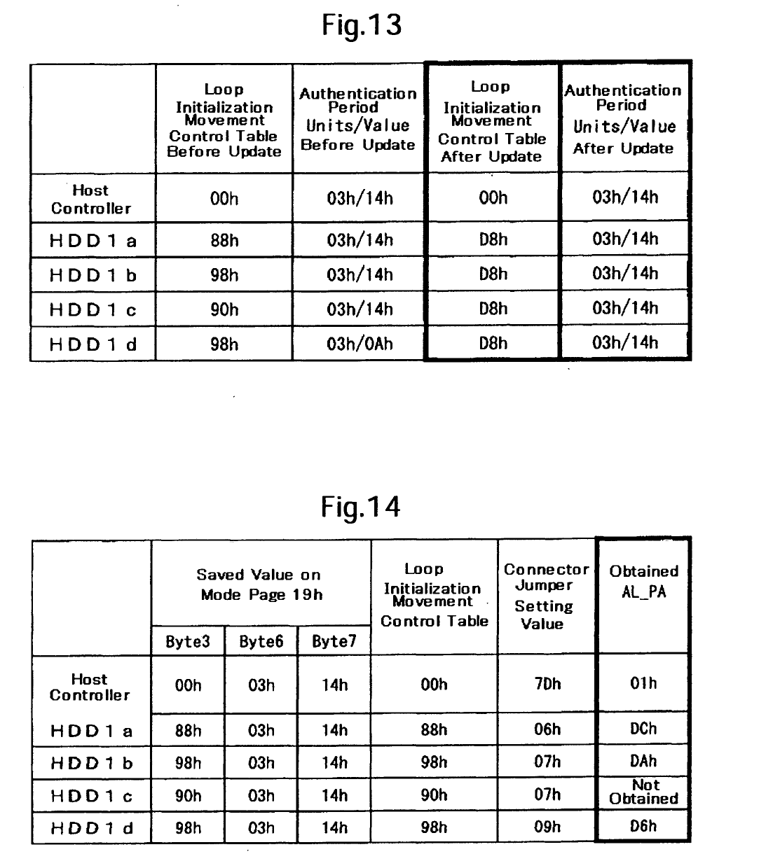

FIG. 12 is a table that shows LIP Order Sets used to perform the above-mentioned loop initialization processing movement and Fibre Channel behavior, and the transitions of Setting Modes, the Loop Initialization Movement Initialization Table, and the authentication times (Units, Value) when these LIP Order Sets are received. As a result, the Loop Initialization Control Tables 241 and the values of authentication time for HDD 1a to HDD 1d are updated as shown in FIG. 13, and the movements that the host controller 2 expects can be realized. FIG. 14 is a table that shows the results of this loop initialization processing, which are what the host controller 2 expects the loop initialization to bring about RHA of HDD 1c is set ON and HDD 1c is in the state that it has not acquired an AL_PA yet.

As mentioned above, even if there is a defect in HDD 1d (the defect of this example is an erroneous jumper setting), performing the initialization processing again after getting rid of the defect (resetting the jumper correctly in this example) can bring about the desired initialization processing results.

Steps S911 to S914 that have been already explained with reference to FIG. 9 will be also described in detail in relation to each Setting Mode.

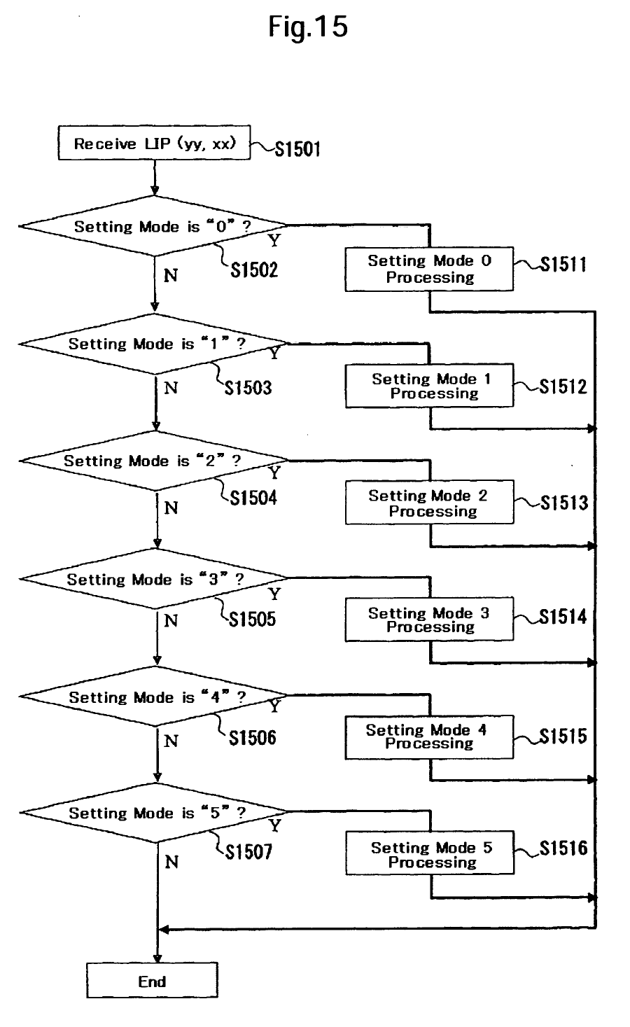

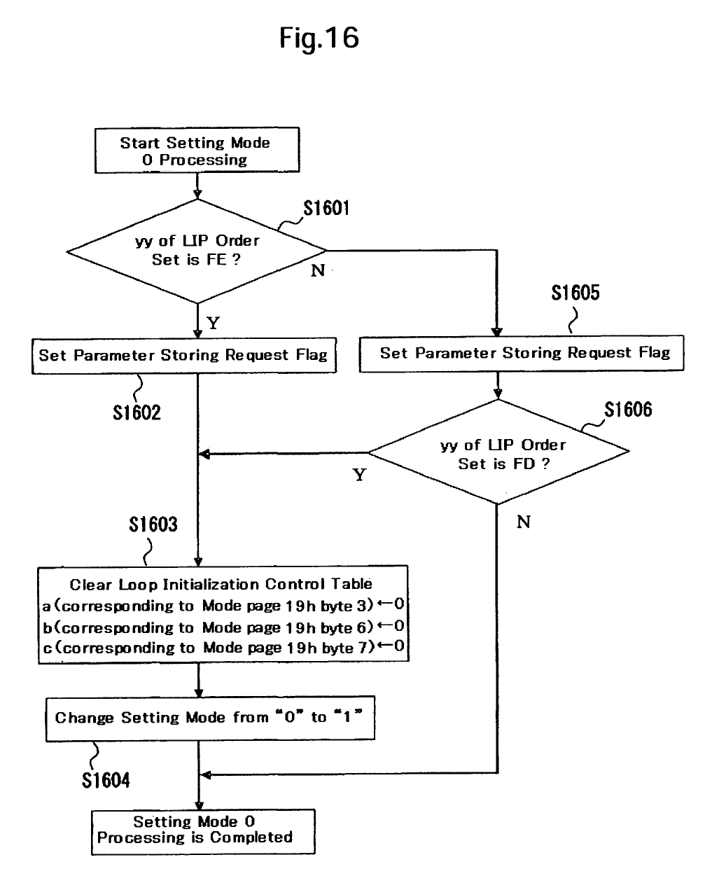

As shown in FIG. 15, when receiving a LIP Order Set (S1501), the loop initialization control unit 231 judges what the setting mode is (S1502 to S1507), and performs the processing according to each setting mode (S1511 to S1516). FIG. 16 is a flowchart showing the processing of Setting Mode 0. The loop initialization control unit 231 judges whether “yy” of the received LIP Order Set (LIP (yy, xx)) is “FE” or not (S1601).

If “yy” is “FE” (branch Y in S1601), the loop initialization control unit 231 sets the parameter storing request flag (S1602), and clears Loop Initialization Control Table 241. To be concrete, it means that 0 is set to a (corresponding to Byte 3 in Mode Page 19h), b (corresponding to Byte 6 in Mode Page 19h), and c (corresponding to Byte 7 in Mode Page 19h). The loop initialization control unit 231 also changes the setting mode from “0” to “1”.

If “yy” is not “FE” (branch N in S1601), the loop initialization control unit 231 resets the parameter storing request flag (S1605). Next, the loop initialization control unit 231 judges whether “yy” is “FD” or not (S1606). If “yy” is “FD” (branch Y in S1606), the loop initialization control unit 231 performs the processing of Step S1603, and it “yy” is not “FD” (branch N in S1606), the processing for Setting Mode 0 ends.

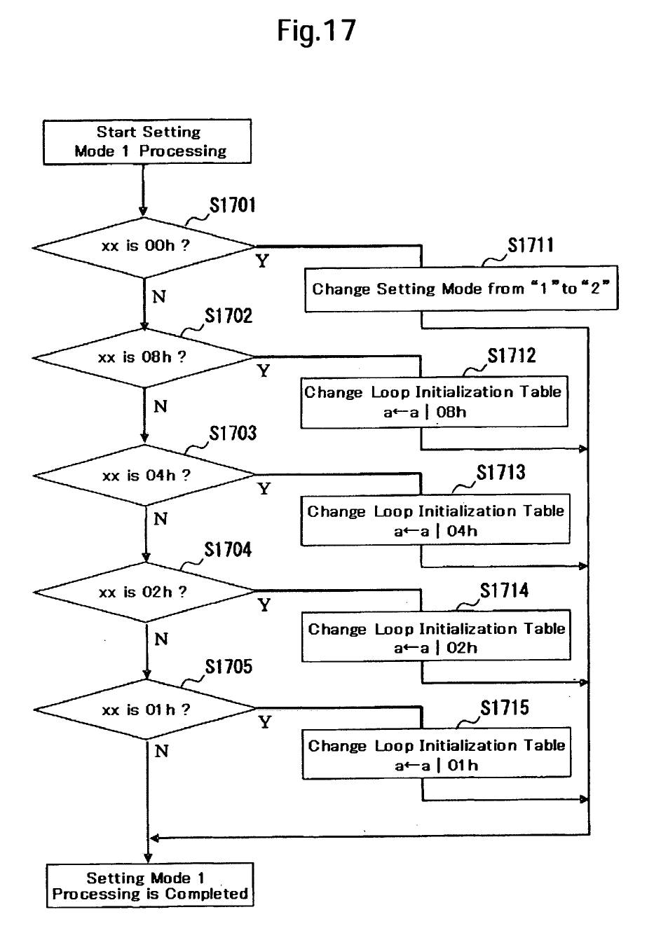

FIG. 17 is a flowchart showing the processing of Setting Mode 1. The loop initialization control unit 231 judges the value of “xx” of the LIP Order Set (LIP (yy, xx)) (S1701 to S1705), and performs the pieces of processing according to the judged values (S1711 to S1715). Here, “a←a|08h” in Step S1712 means that 08h is set to a (corresponding to Byte 3 in Mode Page 19h).

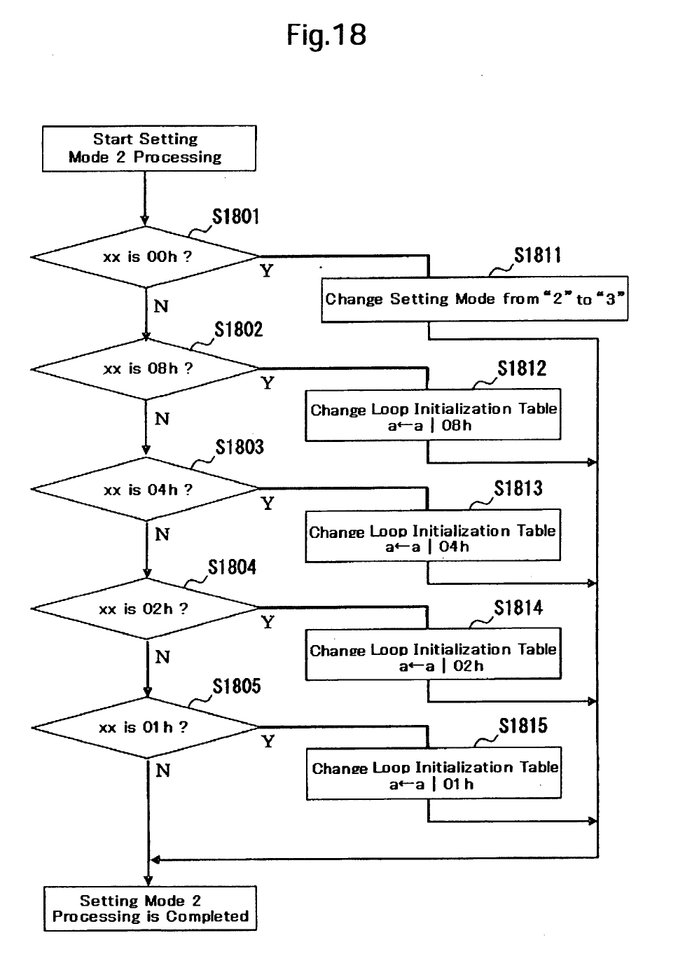

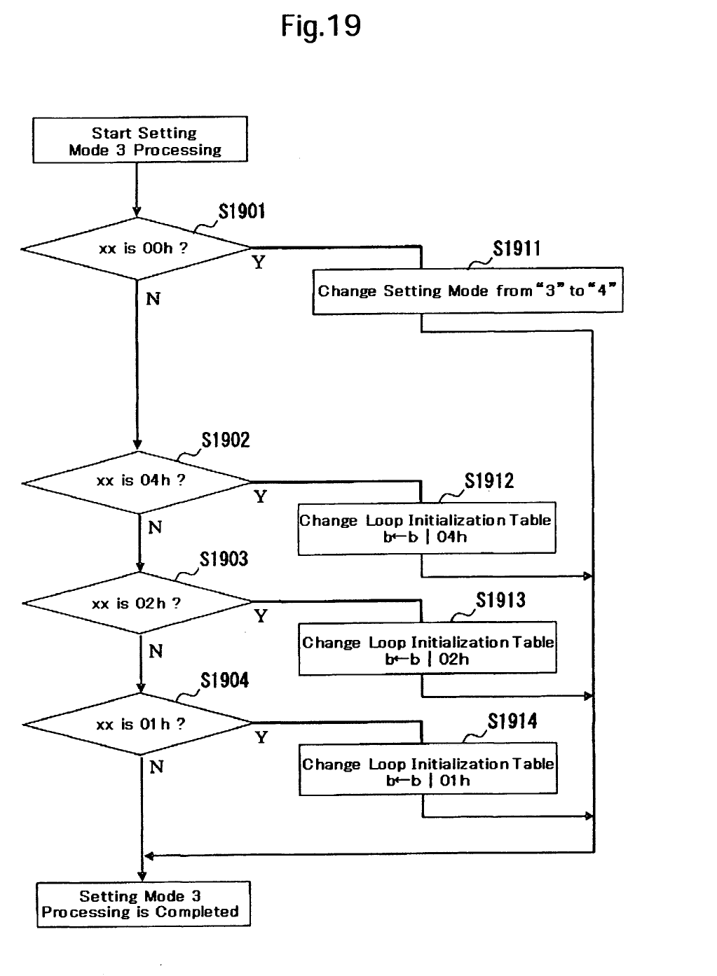

FIG. 18 is a flowchart showing the processing of Setting Mode 2. The loop initialization control unit 231 judges the value of “xx” of the LIP Order Set (LIP (yy, xx)) (S1801 to S1805), and performs the pieces of processing according to the judged values (S1811 to S1815). FIG. 19 is a flowchart showing the processing of Setting Mode 3. The loop initialization control unit 231 judges the value of “xx” of the LIP Order Set (LIP (yy, xx)) (S1901 to S1904), and performs the pieces of processing according to the judged values (S1911 to S1914). Here, “b←b|04h” in Step S1912 means that 04h is set to b (corresponding to Byte 6 in Mode Page 19h).

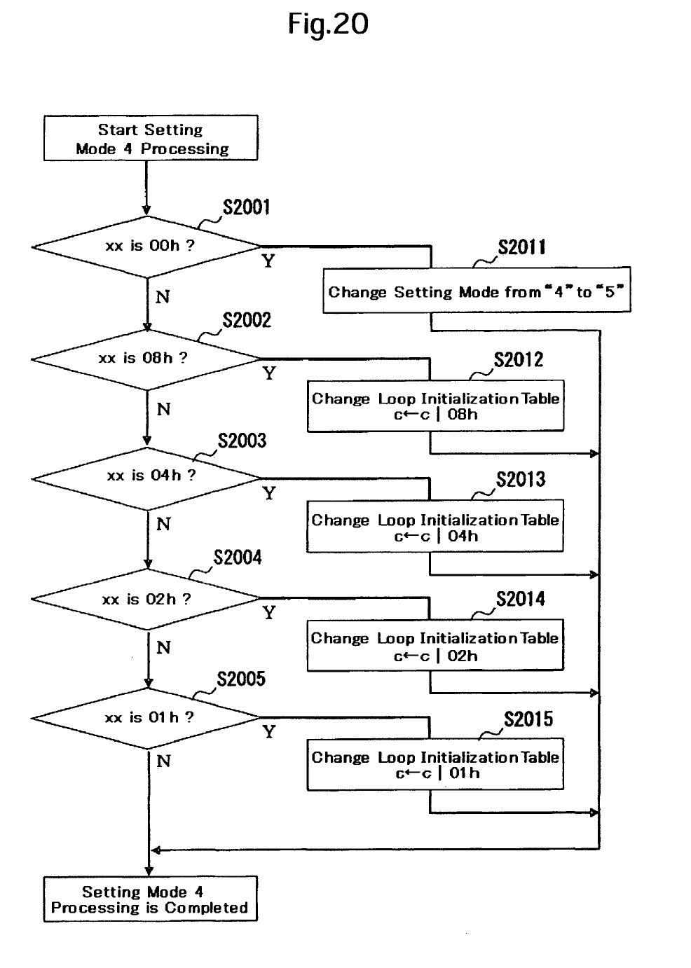

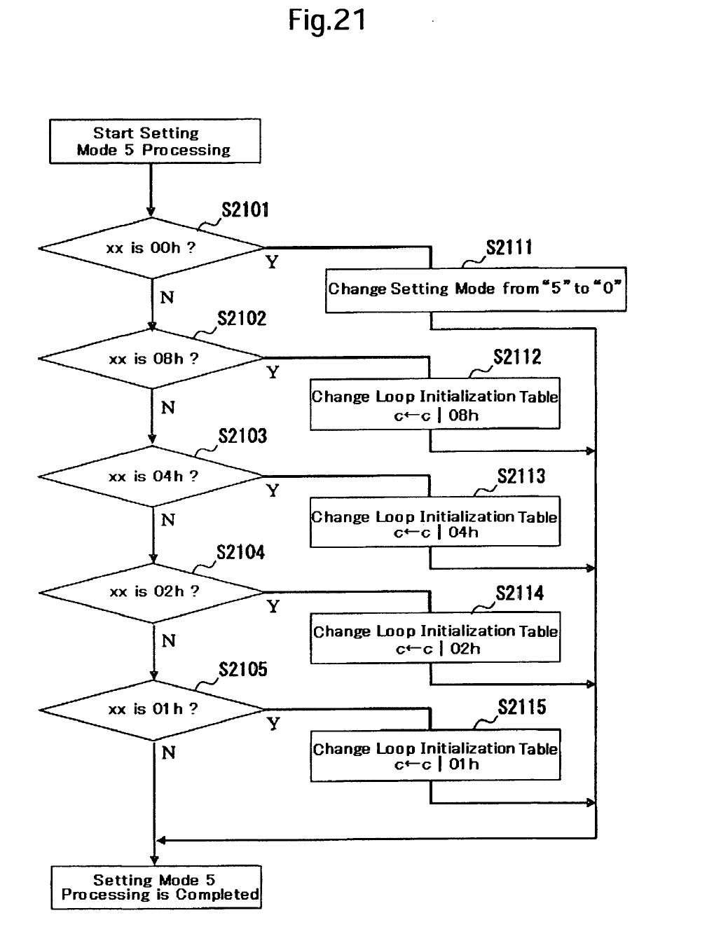

FIG. 20 is a flowchart showing the processing of Setting Mode 4. The loop initialization control unit 231 judges the value of “xx” of the LIP Order Set (LIP (yy, xx)) (S2001 to S2005), and performs the pieces of processing according to the judged values (S2011 to S2015). Here, “c←c|08h” in Step S2012 means that 08h is set to c (corresponding to Byte 7 in Mode Page 19h). FIG. 21 is a flowchart showing the processing of Setting Mode 5. The loop initialization control unit 231 judges the value of “xx” of the LIP Order Set (LIP (yy, xx)) (S2101 to S2105), and performs the pieces of processing according to the judged values (S2111 to S2115).

As described above, it is preferable that the parameters are appended to the LIP Order Set, which is a command to start loop initialization processing. But the parameters can be appended to other control signals that are transmitted on the loop network such as another kind of Fibre Channel Order Set. In the above description, when the LIP Order Set with the parameter xx appended to, the parameter xx is stored in the Loop Initialization Control Table 241, and the initialization processing is performed with the use of the parameter xx.

But it is also possible to allow the initialization processing to have the function to select between the parameter stored in the EEPROM and the received parameter.

As described above, it is preferable to append the parameter xx for controlling the loop initialization movement to LIP Order Sets such as LIP (EF, xx) or LIP (FD, xx) and the LIP Order Sets are transmitted. But it is also possible that the parameter xx is transmitted first on the loop network and set in Loop Initialization Control Table of each HDD of HDD 1a to HDD 1d, and then the LIP Order Sets are sent. In this instance, the LIP Order Sets to be sent can be conventional LIP Order Sets.

### ANOTHER EMBODIMENT OF THE PRESENT INVENTION

Another preferred embodiment of the present invention in which the processing to solve the state of the loop being choked in a loop network such as a FC_AL system by using a high-priority signal such as a LIP Order Set will be described below. In the FC_AL system, an Arbitration signal is communicated between a host controller and a device, and after the one-on-one arbitration between the Host Controller and the device is achieved, the port of the device is opened and the communication is conducted. During the period when the communication is being established, Arbitration signals sent by other devices are discarded by the port that has approved the arbitration. When the communication between the Host controller and the device is finished, the signal showing that effect (Close signal, that is, CLS signal) is transmitted on the loop and the opened port of the device is closed, and then other devices come into the state where they can be arbitrated (idle state).

For example, if Close signal changes or vanishes halfway due to noises and so on without going around the loop network, the opened port does not receive Close signal forever so that it continues to discard the Arbitration signals sent by other devices forever.

Therefore, a new arbitration cannot be reached on the loop network, and the loop network is choked (hanged up).

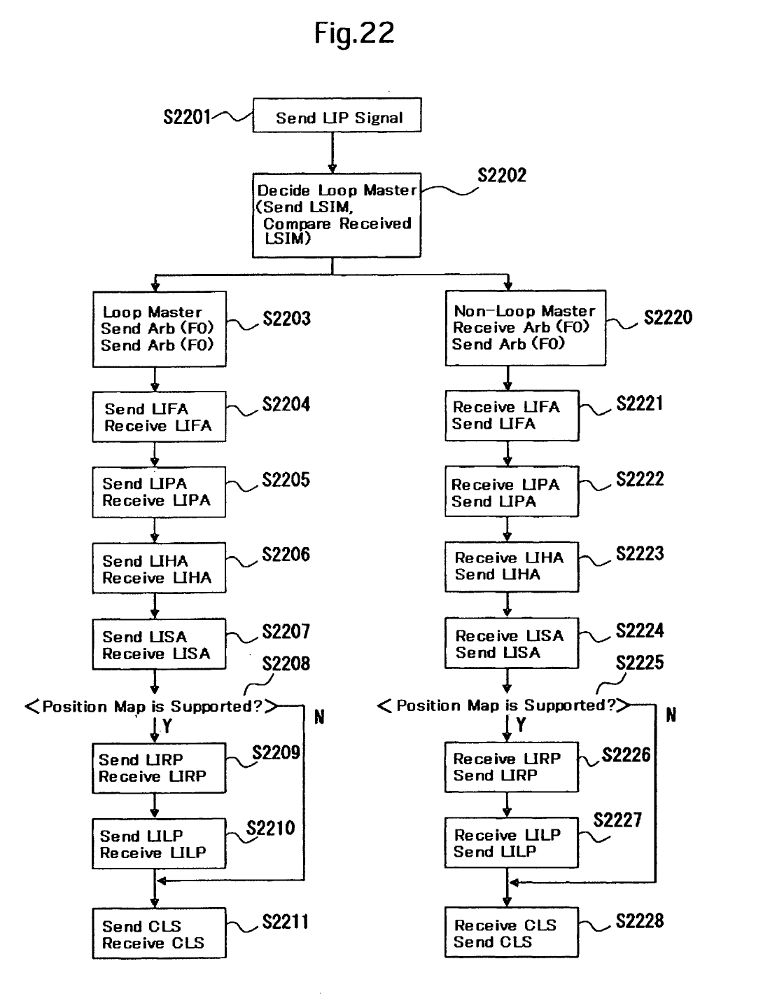

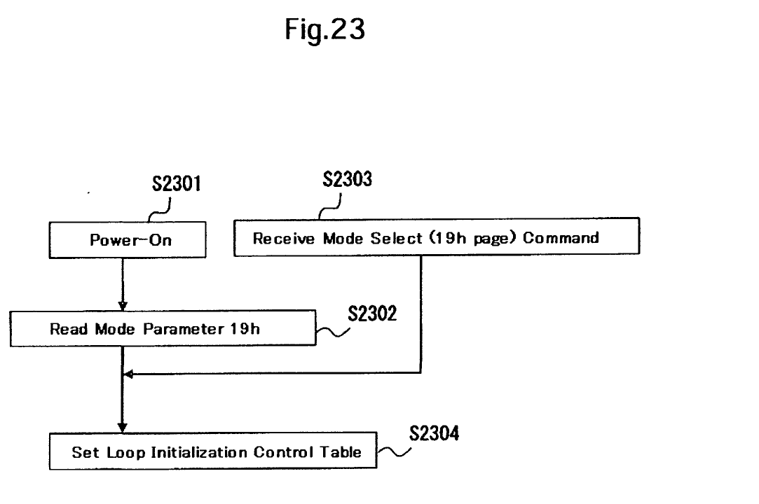

To solve such a situation, a method in which the Host controller sends the LIP Order Set for performing loop initialization processing in order to solve the state of the loop being choked if a predefined time has elapsed without receiving Close signal since sending of Close signal can be taken. This is achieved because a LIP Order Set is a signal to be dealt with the highest priority in the FC_AL system, and each port must participate in loop initialization when receiving a LIP Order Set even if it is either in the open state or in the closed state. After the LIP Order Set goes around the loop network, a loop initialization frame that is described with reference to FIG. 22 is transmitted on the loop, and Close signal goes around the loop at the final stage of the loop initialization so that the state of the loop being choked is solved.

However, in the case of the above-mentioned method to solve the state of the loop being choked, AL_PA acquiring processing, which is described with reference to FIG. 22, according to the conventional art is naturally performed at each port too. As a result, it takes finally a long time for the loop to recover from the state of being choked if the processing time for each port is taken into account. If the loop initialization frame is broken during the loop initialization, the AL_PA of each port changes so that there is a possibility that system failure will occur. The recovery processing from loop choking of this embodiment of the present invention can solve the above-mentioned problem by omitting at least part of the ordinal processing performed by conventional LIP Order Sets.

Concrete recovery method from the loop choking of this embodiment of the present invention will be described with the use of FIG. 2. For example, let's discuss the case where the arbitration between the Host controller 2 and the HDD 1c is approved and data sent from the Host controller 2 to the HDD 1c is written into the HDD 1c. In this instance, because the receiving port of the HDD 1c is open, the Arbitration signals sent by other devices are discarded by the receiving port of the HDD 1c.

Because the communication between the Host controller 2 and the HDD 1c ends when writing data into the HDD 1c is completed, Close (CLS) Signal is sent by the HDD 1c. This Close signal is transmitted through the HDD 1d, the Host controller, HDD 1a, and HDD 1b in this order, and reaches to the HDD 1c. Then the receiving port of the HDD) 1c returns to the closed state, and transfers the Arbitration signals of other nodes to the downstream.

The processing related to the case where the Close signal sent by HDD 1c changes or vanishes halfway due to noises and so on without going around the loop network will be described below. The following pieces of processing in each HDD are performed by the HDC/MPU 23 of each HDD. The HDD 1c sends the Close signal and at the same time begins time measurement. If the Close signal does not return within a predetermined period (time-out), the HDD 1c judges whether the loop is choked. The HDD 1c appends the loop choking flag, which is a predefined special identifying code, to a LIP Order Set, and sends the LIP Order Set. This LIP Order Set goes around the loop network from the HDD 1c to HDD 1d, the Host controller 2, HDD 1a, and HDD 1b, and returns back to HDD 1c.

Each port skips the decision of Loop Master (S2202), and the acquisition processing of an address on the loop network (S2203 to S2210 and S2220 to S2228) that are described related to the conventional art with reference to FIG. 22. The HDD 1c sends the Close signal when it receives the LIP Order Set that it sent itself. The Close signal goes around the loop network from the HDD 1c to HDD 1d, the Host controller 2, HDD 1a, and HDD 1b, and returns back to HDD 1c, resulting in the end of the processing. As a result, the receiving port of the HDD 1c is closed, and the Arbitration signals of other ports are normally transferred on the network.

In this way, skipping the acquisition processing of an address at each port allows the loop to recover from the state of the loop choking with the use of a type of control signal of a LIP Order Set, and at the same time it can reduce the processing time and suppress the probability of defect occurrence. As mentioned above, it is preferable to skip the decision of Loop Master and the acquisition processing of addresses, but some pieces of processing other than the acquisition processing of addresses such as the decision of Loop Master can be performed depending on the types of designs. Alternatively, another recovery method in which each port neither performs the acquisition processing of an address nor appends information to its initialization frame, and only transfers the LIP Order Set can be configured. Another recovery method in which a node other than HDD 1c can transfer the LIP Order Set can be also configured. In addition, a control signal other than the LIP Order Set can be used as long as the state of the loop choking is solved.

Another recovery method in which the HDD 1c that detects the time-out sends a LIP Order Set again in order to solve the state of the loop choking can be also considered. Although the state of the loop choking is also solved in this case, this method is not preferable because there is a possibility that other defects will occur. For example, if the first Close signal sent by the HDD 1c returns to the HDD 1c after the HDD 1c sends the second Close signal, the second Close signal remains on the loop. This remaining Close signal has a possibility to cause defects. For example, it may stop the communication related to the arbitration approved afterward before the communication is completed.

In the recovery method from the loop choking described in this applicable embodiment of the present invention, even when the first Close signal sent by the HDD 1c returns to the HDD 1c after the HDD 1c sends the LIP Order Set with the loop choking flag appended to, the occurrence of defects due to the useless Close signal remaining on the loop can be avoided.

Although the present invention has been described taking its preferred applicable embodiments as examples, the present invention is not limited to these embodiments. The elements of the applicable embodiments of the present invention can be easily changed, added and modified without departing from the scope of the present invention by those skilled in the art. For example, the present invention is suitable for use in a loop network with data storage devices as nodes, but devices other than the data storage devices can be added to the loop network.

What is claimed is:

1. A loop network system comprising a loop network and multiple nodes connected thereto, wherein the multiple nodes include:
a control node for sending parameters for controlling initialization processing performed by the nodes in order to perform data communication in the loop network to the downstream of the loop network system; and
controlled nodes that receives the parameters, performs the initialization processing according to the received parameters, and transfers the received parameters to the downstream of the loop network.

2. The system according to claim 1, wherein the parameters for controlling the initialization processing are transmitted among nodes in the loop network in the form of appendices to the execution start command of the initialization processing.

3. The system according to claim 1, wherein at least part of the multiple nodes further include nonvolatile storage media to store the parameters for controlling the initialization processing and receive the instruction to store the parameters in the nonvolatile storage media or not as well as the parameters.

4. A data storage device that is connected to a loop network and is used for data communication, comprising:
a receiving unit that receives parameters through the loop network;
an initialization control unit that performs initialization processing according to the parameters received by the receiving unit in order to perform data communication in the loop network from the upstream of the loop network; and
a transmitting unit that transfers the parameters received by the receiving unit to the downstream of the loop network.

5. The data storage device according to claim 4, further including nonvolatile storage media for storing parameters for controlling the initialization processing, wherein the parameters stored in the nonvolatile storage media are overwritten according to the instruction received with the parameters.

6. The data storage device according to claim 4, wherein:
the receiving unit that receives the parameters for controlling the initialization processing as well as the execution start command of the initialization processing; and
the transmitting unit sends the parameters for controlling the initialization processing as well as the execution start command of the initialization processing.

7. A loop network system comprising a loop network and multiple nodes connected thereto, wherein:
when one of the multiple nodes judges that the loop is choked, the node sends a control signal according to which each node performs the processing as well as a preset identifier even if the loop is choked; and
the other multiple nodes starts the processing corresponding to the sent control signal, and at the same time omits at least part of the ordinal processing corresponding to the control signal according to the identifier.

8. The system according to claim 7, wherein:
the control signal instructs how to perform loop initialization processing; and
each of the multiple nodes omits the acquisition processing of an address on the loop network in the loop initialization processing.

9. A data storage device that is connected to a loop network and is used for data communication, comprising:
a judgment unit that judges whether the loop is choked;
a transmitting unit that sends a control signal according to which processing is performed as well as a preset identifier even when the loop is choked; and
a control unit that performs the processing according to the control signal, while omitting at least part of the ordinal processing corresponding to the control signal.

10. The device according to claim 9, wherein:
the control signal instructs how to perform loop initialization processing; and
the control unit omits the acquisition processing of an address on the loop network.
